(19) United States
(12) Patent Application Publication
(10) Pub. No.: US 2011/0121387 A1
(43) Pub. Date: May 26, 2011

(54) INTEGRATED GUARDED SCHOTTKY DIODE COMPATIBLE WITH TRENCH-GATE DMOS, STRUCTURE AND METHOD

(76) Inventors: Francois Hebert, San Mateo, CA (US); Dev Alok Girdhar, Indialantic, FL (US)

(21) Appl. No.: 12/770,074

(22) Filed: Apr. 29, 2010

Related U.S. Application Data
(60) Provisional application No. 61/263,618, filed on Nov. 23, 2009.

(51) Int. Cl. H01L 21/336; H01L 29/78

(52) U.S. Cl. 257/334; 438/270; 257/E21.417; 257/E29.256

(57) ABSTRACT

A plurality of transistor cells, each of which can include a transistor P-body region and a Schottky diode, wherein the transistor P-body region can be formed below the Schottky diode to provide a semiconductor device having desirable electrical characteristics.

### CROSS REFERENCE TO RELATED APPLICATION

This application claims priority to provisional U.S. Patent Application Ser. No. 61/263,618 filed Nov. 23, 2009, which is incorporated herein by reference in its entirety.

### DESCRIPTION OF THE EMBODIMENTS

Reference below is made in detail to the present embodiments (exemplary embodiments) of the present teachings, examples of which are illustrated in the accompanying drawings. Wherever possible, the same reference numbers will be used throughout the drawings to refer to the same or like parts. Also, for purposes of the present teachings, the terms “Schottky,” “Schottky diode,” and “Schottky contact” are used interchangeably. The drawings, which are incorporated in and constitute a part of this specification, illustrate embodiments of the invention and together with the description, serve to explain the principles of the invention. In the figures:

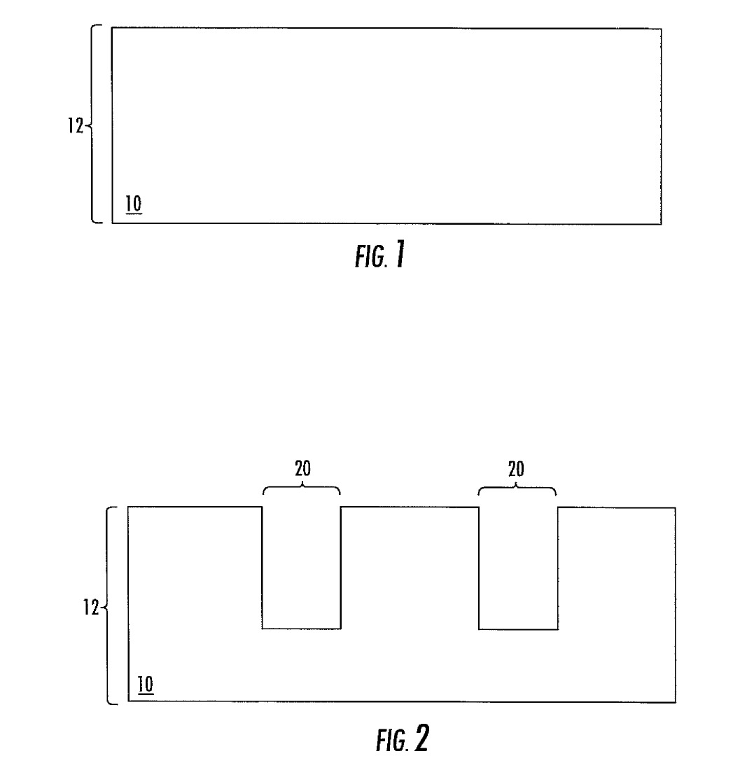

FIGS. 1-10 are cross sections depicting intermediate structures that can be formed using an embodiment of the present teachings;

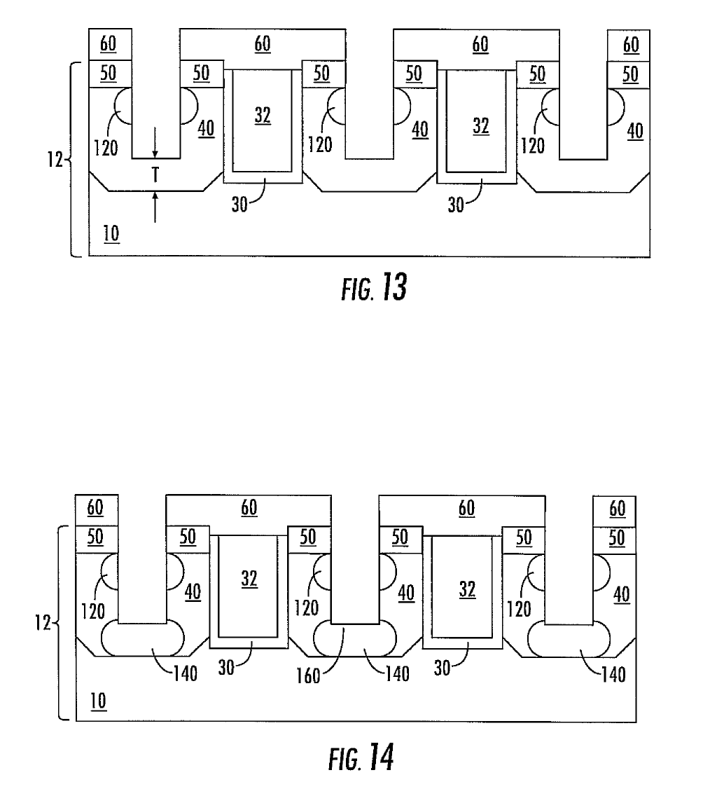

FIG. 11-15 are cross sections depicting intermediate structures that can be formed using an embodiment of the present teachings;

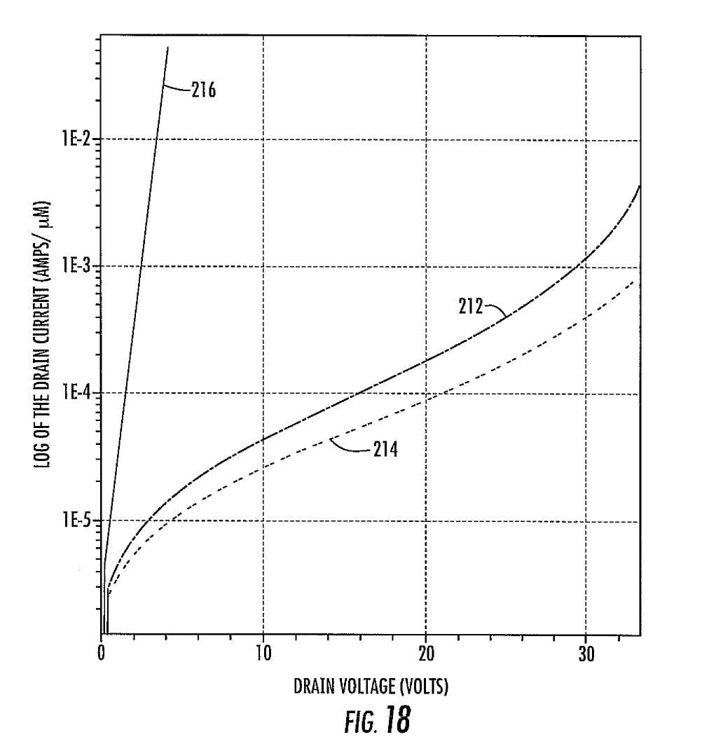

FIG. 16 is a cross section depicting a structure that can be formed in accordance with the present teachings;

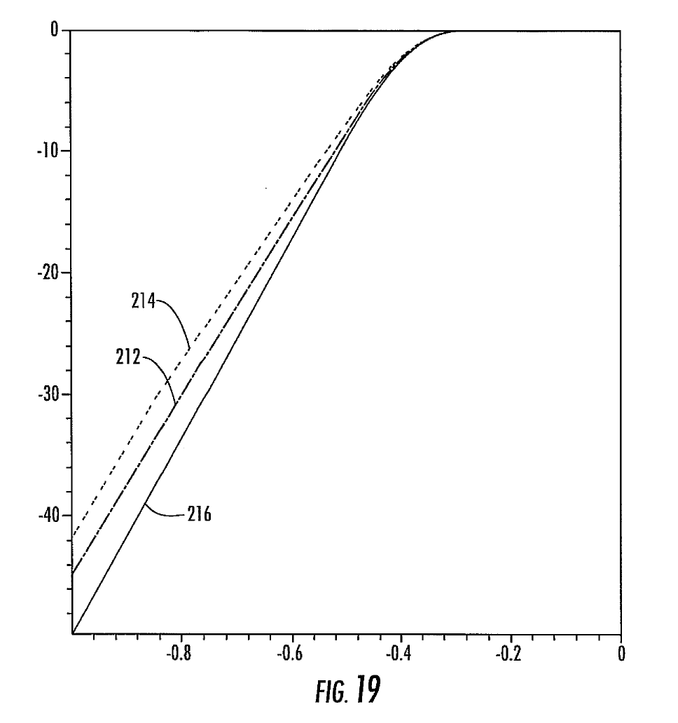

FIG. 17 is a graphic depiction of doping levels for exemplary devices which can be formed in accordance with an embodiment of the present teachings;

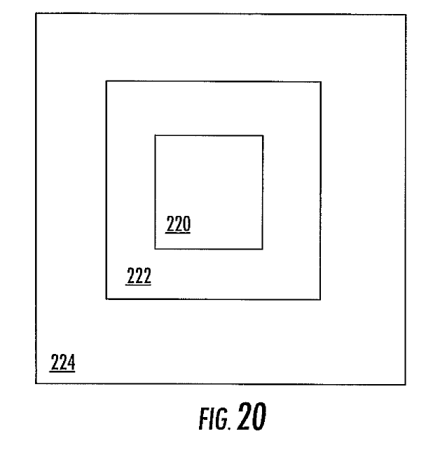

FIGS. 18 and 19 are graphs which depict operational characteristics of various devices formed in accordance with the present teachings; and

FIG. 20 is a block diagram depicting a voltage regulator having a Schottky contact in accordance with the present teachings used within an electronic system.

It should be noted that some details of the FIGS. have been simplified and are drawn to facilitate understanding of the inventive embodiments rather than to maintain strict structural accuracy, detail, and scale.

Devices in accordance with the present teachings can integrate with trench gate diffused metal oxide semiconductor (DMOS) processes that use a trench contact which contacts both a source region and a P-body contact region. This trench contact may also be referred to as a source contact with a recessed body contact. Further, embodiments can include the use of a shallow silicon etch to remove an undesirable heavy body contact implant at a trench bottom, which can be useful because a Schottky cannot be formed in a highly doped silicon region. The use of counterdoping (i.e. a doping a region having a first type conductivity with a dopant having an opposite type conductivity) can be employed to adjust a barrier height of the Schottky contact by changing the surface doping concentration, and to change an injection efficiency of a diode formed between a P-body and a transistor drain region.

Additionally, counterdoping can be used for several purposes, for example: to form a low injection body diode; to create a junction field effect transistor (JFET) underneath the Schottky diode with a metal oxide semiconductor field effect transistor (MOSFET) P-body functioning as a gate, and; to counterdope the P-body and add one or more tuning implants to adjust forward voltage and leakage current characteristics.

In an embodiment, tuning implants can be P-type for an N-channel device or N-type for a P-channel device. Additionally, a structure can be formed which includes a self-aligned shield (guard) at a periphery of the Schottky diode to reduce leakage under high reverse bias conditions.

A structure according to an embodiment of the present teachings can include a trench-gate diffused metal oxide semiconductor (DMOS) device having a recessed contact to the P-body and the source and a counterdoped Schottky or low-injection diode between the P-body region and the drain region. A method for forming such a device is depicted in FIGS. 1-10. In this embodiment, formation of an N-channel MOS (NMOS) device will be depicted and described, but it will be realized that a structure including a P-channel device (PMOS), or both PMOS and NMOS devices, can be formed by adjusting masks, implants, etc.

In FIG. 1, a substrate 10 such as a semiconductor wafer, a semiconductor wafer section, an epitaxial layer, etc. having a thickness 12 is provided. In this embodiment, the substrate 10 includes an epitaxial silicon layer doped to an N-type conductivity formed on an N+ semiconductor wafer.

After providing the FIG. 1 structure, transistor gate trenches 20 such as those depicted in FIG. 2 can be provided at transistor gate locations. Formation of the transistor gate trenches can include an optical photolithography process and a silicon etch. An optional isotropic etch can be performed to shape the transistor gate trenches to increase fill, followed by a sacrificial oxide growth, an oxide etch, and mask removal, to result in the FIG. 2 structure.

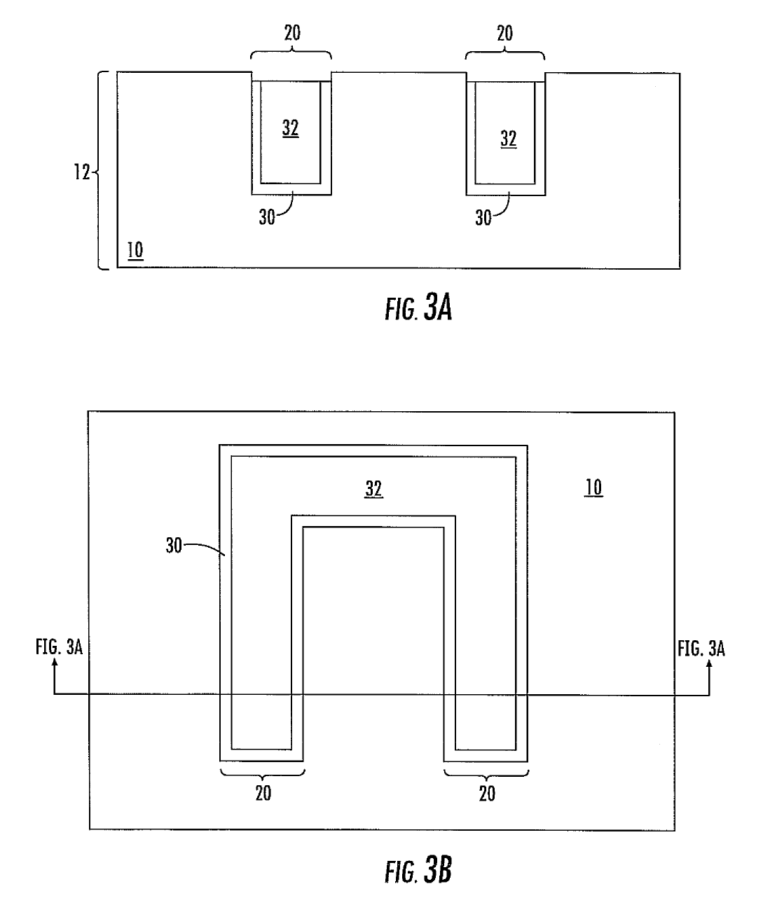

Next, a transistor gate dielectric 30 can be formed, for example using a gate oxidation process to result in transistor gate dielectric 30 as depicted in FIGS. 3A and 3B, in which FIG. 3A is a cross section along the plan view location shown in FIG. 3B. A polysilicon deposition, implantation with an N-type dopant such as arsenic or phosphorous, and a polysilicon etchback can be performed to result in the FIGS. 3A and 3B structure including polysilicon structures 32 which will provide one or more transistor gates for the completed device.

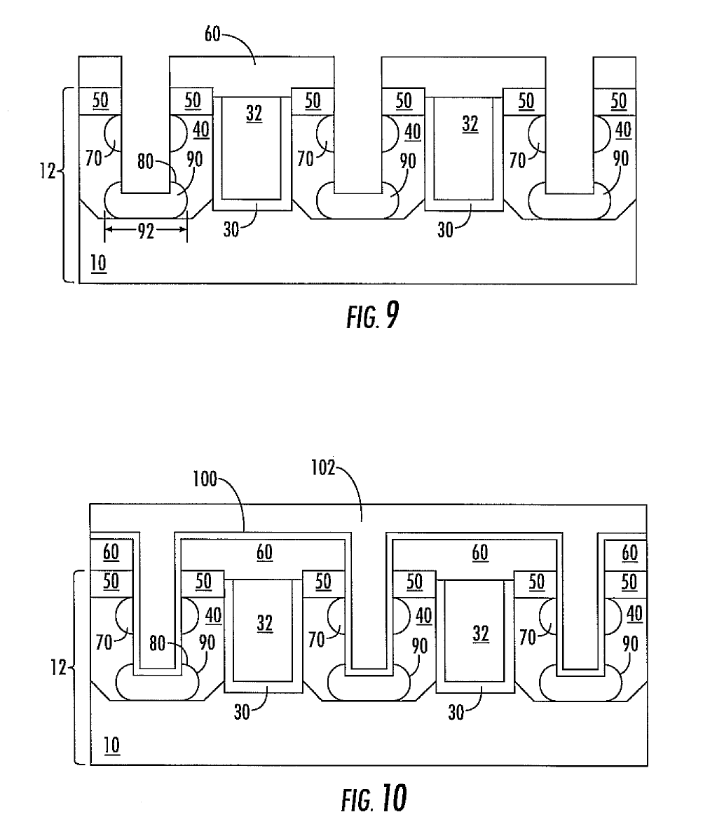

As shown in FIGS. 3A and 3B, the transistor gate trenches 20 depicted in cross section may be separate portions of the same transistor gate trench which encloses an area. Separate cross-sectional sidewalls may be, in actuality, two parts of one continuous sidewall, the transistor gates 32 which are depicted as being separate in FIG. 3A may be two portions of the same transistor gate as depicted in FIG. 3B. Similarly, subsequently formed P-body contact regions (for example 70 in FIG. 7) which are depicted as being separate may be portions of the same P-body contact region. The area enclosed by the transistor gate may be circular, rectangular, hexagonal, etc., when viewed from above. These features of this and other embodiments in the description and claims may be depicted and described herein as first and second sidewalls, trenches, etc. for ease of explanation.

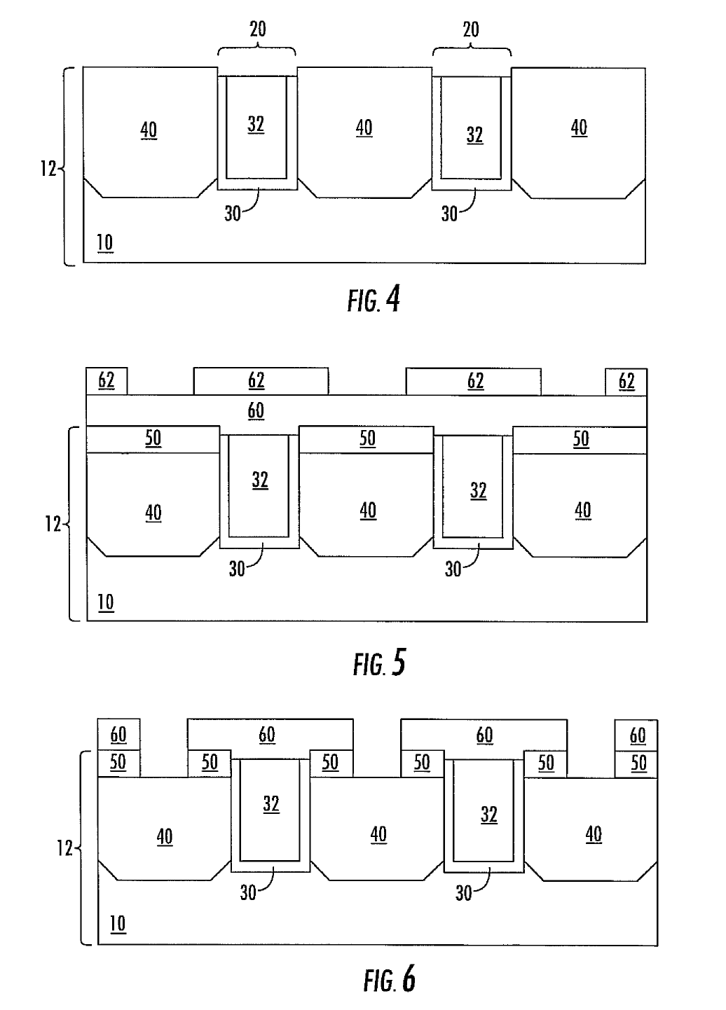

Subsequently, an optical lithography process using a patterned P-body mask followed by a P-type implant of boron can be used to form P-body regions 40. The P-body mask is stripped and a P-body drive anneal can be performed to result in the P-body regions 40 as depicted in FIG. 4.

After forming the structure of FIG. 4, processing can continue to form the FIG. 5 structure. Source regions 50 can be formed by an N-type implant through a mask which covers polysilicon transistor gates 32. The N-type implant can include an arsenic dopant to a dose of between about 2E15 atoms/cm² and about 10E15 atoms/cm² at an implant energy of between about 40 KeV and about 150 KeV. This will counterdope the upper part of the substrate 10 and P-body region 40 to form source regions 50.

Next, between about 1,000 Å and about 8,000 Å of oxide can be deposited to form oxide layer 60. Optionally, an undoped oxide can be formed, for example in the range of between about 500 Å to about 2,000 Å and between about 1,000 Å and 8,000 Å, for example using borophosphosilicate glass (BPSG). A source anneal can be performed using a flow of oxygen at a temperature of between about 850° C. and about 950° C. for between about 10 minutes and 60 minutes. A patterned mask 62 is formed which exposes a portion of oxide 60, source regions 50, and P-body regions 40 to complete the FIG. 5 structure.

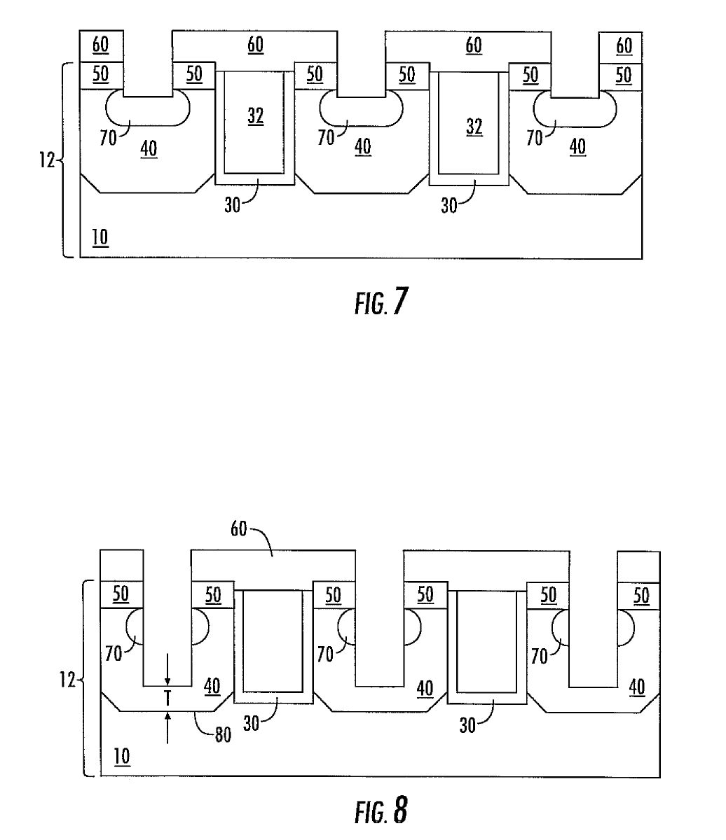

After forming a structure similar to that of FIG. 5, one or more etches are performed to remove exposed portions of oxide 60 and source regions 50, and to expose P-body regions 40. The etch can stop after etching through the thickness of the source region 50 as depicted. In another embodiment, a slight over etch into P-body regions 40 (for example, as depicted in FIG. 7) will ensure separation of source regions 50. After removing mask 62, a structure similar to that of FIG. 6 remains. This etch forms a trench with first and second sidewalls, and separates each source region 50 between the transistor gates 32, such that source regions for adjacent transistor gates are electrically isolated from each other.

After exposing P-body regions 40 as depicted in FIG. 6, a P-body contact dopant implant using boron or BF₂ at a tilt of 0° can be performed through the openings in the oxide 60 and in the source regions 50 to form the FIG. 7 structure. The dopant is implanted into the upper surface of the P-body regions 40 with P-type material to form heavily-doped (P+) P-body contact regions 70 below a surface of the semiconductor substrate and below the source regions 50. The implant can be performed at an energy of between about 5 KeV and about 60 KeV and a dose of between about 5E14 atoms/cm² to about 4E15 atoms/cm². An optional anneal using a rapid thermal processing (RIP) at a temperature of between about 900° C. to about 1,000° C. in a nitrogen (N₂) environment can be performed to activate the implant dopants with minimal diffusion, resulting in a structure similar to FIG. 7.

Subsequently, a silicon etch that etches through the heavily doped P-body contact regions 70 and partially etches into the P-body region 40 can be performed to extend the sidewalls. Etching partially into the P-body region 40 helps to ensure that a portion of the P-body region of the completed device will remain below a subsequently formed Schottky diode, so that the P-body region can function as a shield. The shield will be provided in this embodiment by a P-body region below the level of the subsequently formed Schottky between the Schottky and an adjacent transistor trench gate. This results in the structure of FIG. 8, in which the P-body contact regions 70 are within the sidewall of the trench (i.e., P-body contact regions 70 abut the sidewalls of the trench).

The depth of the etch through P-body contact regions 70 can vary. In the FIG. 8 embodiment, a thickness of the P-body region 40 which remains below the trench can have a remaining thickness “T” which is between about 0.01 μm and about 0.4 μm. Throughout the remainder of this document, the value of the remaining thickness of the P-body region from the bottom of the trench to the bottom of the doped P-body region 40 will be referred to as “T”. In FIG. 8, a P-body junction 80 at this stage in the process is formed by an interface between the lower extent of the P-type doped region which forms P-body region 40 and the N-type doped substrate 10. At later processing stages, the location of the P-body junction will change due to subsequent doping processes.

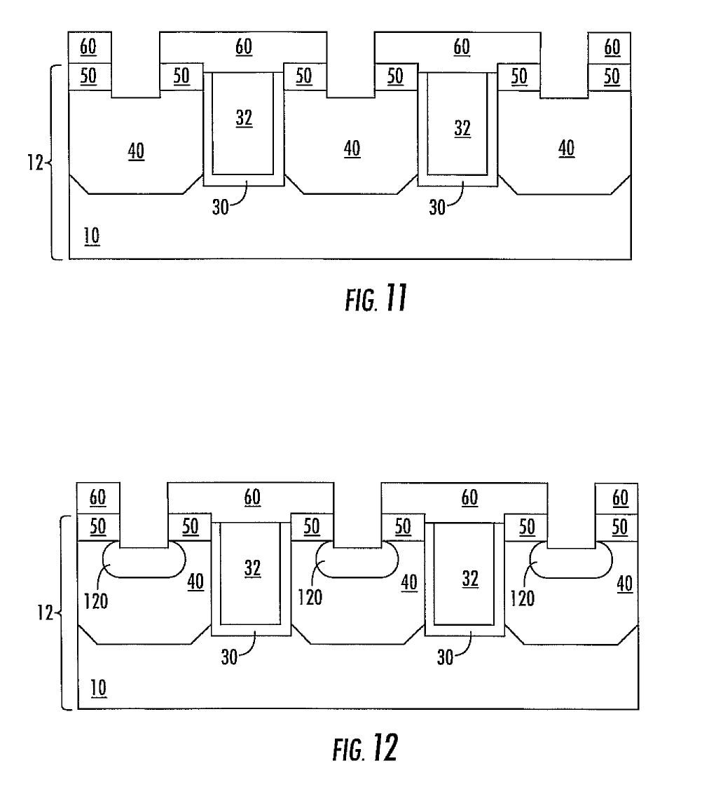

Next, one or more N-type compensation implants using phosphorous or arsenic to a dose of between about 5E10 atoms/cm² to about 1E14 atoms/cm² can be performed to form N-type doped N-type compensated regions (i.e. “N-compensated regions” or “N-compensation regions”) 90 as depicted in FIG. 9. The implant process can include 0° tilt and an implant energy of between about 5 KeV and about 100 KeV. This dose and energy of compensation implant is chosen to ensure that a net doping (i.e. charge) of the substrate remaining between opposing P-body regions (i.e. P-body regions on either side of the trench) has a dose of between about 1 E11 atoms/cm² and about 1E13 atoms/cm². An optional anneal can be performed. Because of the implanted N-compensation regions 90, the P-body junction 80 in FIG. 9 is now at the interface between N-compensation region 90 and P-body region 40.

Next, a patterned contact mask is formed, for example to expose the transistor gates 32 at locations which are not depicted in the FIG. 10, and a dielectric etch is performed to etch dielectric 60 overlying the transistor gates at the other locations. After a contact mask strip, a short oxide etch is performed to remove any native oxide from exposed portions of region 90 at the bottom of the trenches in FIG. 9. One or more layers of conductor such as a metal which can include titanium and titanium nitride 100 are deposited as depicted in FIG. 10. Optional tungsten plugs can be formed at locations not depicted in FIG. 10 to provide a contact to the sources 50, a contact to the P-body 40, or both types of contacts. Next, hot or cold aluminum 102 and a metal mask can be formed to result in a structure similar to FIG. 10. In the FIG. 10 device, transistor drains are provided by the N-type substrate region 10 which maintains its original N-type conductivity. Contact to the transistor drains can be made through the bottom of the N-type substrate 10.

The Schottky diode is provided in the FIG. 10 structure by contact between the metal 100 and the N-compensated regions 90. The shielding of the Schottky region is provided by the P-body region 40 which is adjacent to the N-compensated regions 90. The shielded Schottky diode in this MOSFET structure by this method is provided without requiring any additional area in the lateral direction. The resulting Schottky diode can achieve low leakage because of shielding regions below a level of the Schottky contact without increasing the distance between adjacent transistor gates of the MOSFET. In other words, the shielded Schottky diode structure does not increase the area of the MOSFET, for example when used in a power MOSFET device.

Another embodiment of the present teachings is depicted in FIGS. 11-14. This embodiment can result in a DMOS device with a trench gate having a recessed contact to the source and P-body region. The P-body region is continuous at the bottom of the trench, and thus the P-body region is directly below the Schottky. Partial counterdoping below the bottom surface of the trench can be employed.

To form this structure, an embodiment can include a portion of the prior process, up to and including the structure depicted in FIG. 5. The patterned mask 62 and one or more etches can be formed to clear dielectric 50 which overlies the P-body regions 40 to result in the FIG. 11 structure, which depicts a slight over etch of the source regions 50 to ensure separation of adjacent source regions.

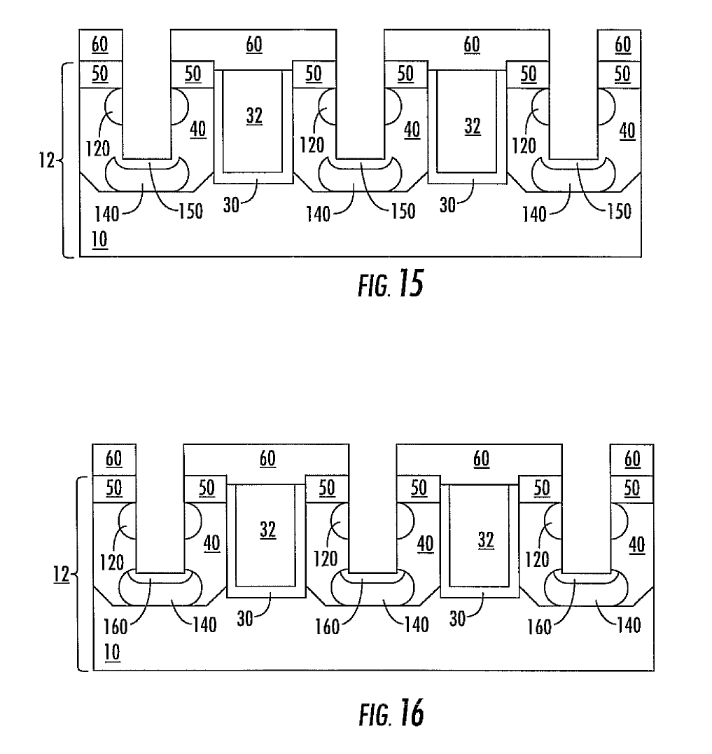

Next, a body contact implant at 0° tilt can be performed using boron or BF₂ at an implant energy of between about 5 KeV and about 60 KeV, to a dose of between about 5E14 atoms/cm² to about 4E15 atoms/cm². An optional anneal using RTP at about 900° C. to about 1,000° C. for between about 20 seconds and 60 seconds can be performed in an N₂ environment to activate the implant dopants with minimal diffusion to form doped P-body contact regions 120 and result in a structure similar to that depicted in FIG. 12.

Next, a silicon etch can be performed that partially etches into the P-body 40 as depicted in FIG. 13. The partial etch helps ensure that a lower extent of the P-body exists below a level the Schottky diode between the Schottky and an adjacent transistor gate to function as a shield to reduce leakage. As depicted in FIG. 13, a thickness “T” of at least 0.01 μm of the P-body can remain.

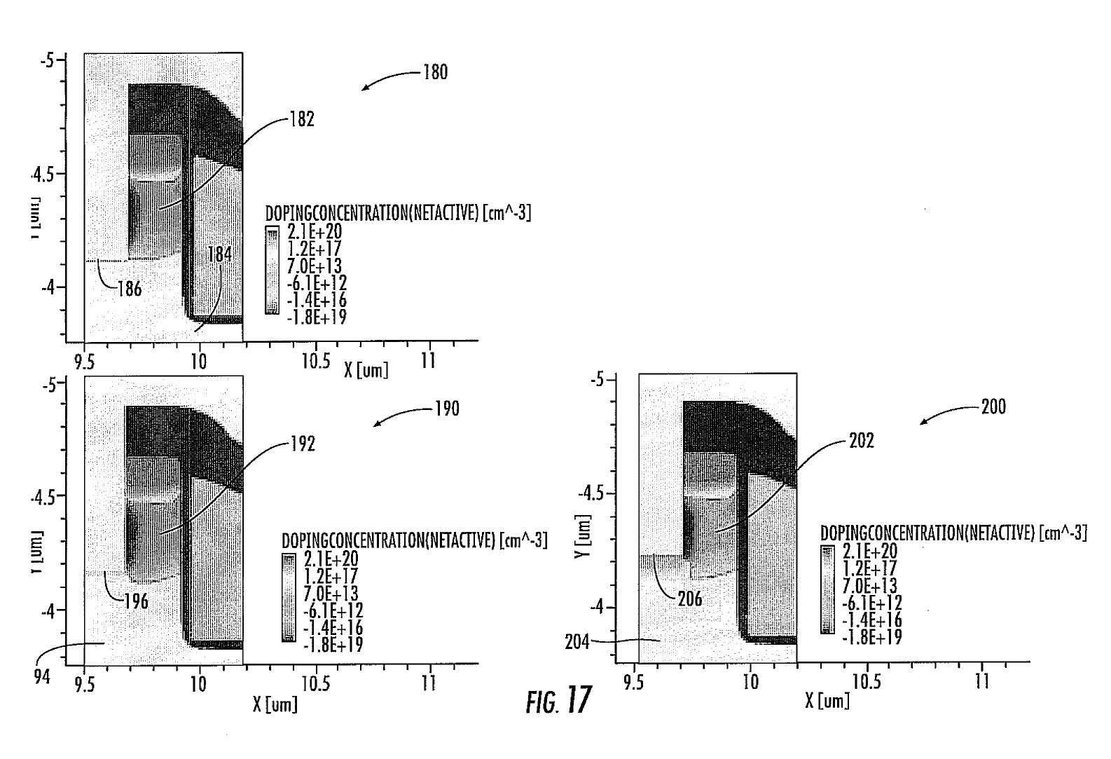

After forming the FIG. 13 structure, one or more N-type compensation implants, for example using phosphorous and/or arsenic, can be performed at 0° tilt using an energy of between about 5 KeV and about 100 KeV to a dose of between about 5E10 atoms/cm² to about 1E15 atoms/cm² to result in the doped regions 140 of the FIG. 14 structure. An optional anneal can be performed to activate the implant dopants with minimal diffusion.

Next a P-type tuning implant can be performed to adjust a net doping level at the surface of the N-compensated regions 140 to a desired level, for example less than about 1E17 atoms/cm³. This ensures that the amount of charge between opposing P-body regions 40 is at a dose of between about 1E11 atoms/cm² and about 1E13 atoms/cm². This can be followed by a low temperature anneal, for example an RTP at a temperature of between about 600° C. and about 800° C. for a duration of between about 10 seconds and about 60 seconds in an N₂ environment, which results in the tuned implanted P region 150 of the FIG. 15 structure. Thus the P-type tuning implant results in the FIG. 15 structure in which the P-type tuning implant, in effect, recesses the N-type compensated regions below the surface of the opening. The Schottky metal deposited at a later step in the process flow (similar to metal 100 and 102 in FIG. 10, for example) will form a contact to a very thin p-type region and functions as a very poor PN diode. Such a low-injection efficiency diode can be helpful in power MOSFET devices to control reverse recovery characteristics of the P-body diode during switching of the power devices. Wafer processing can then continue to form a completed device, for example to form transistor gate contacts, metallization, etc.

In an alternate embodiment (not depicted), a thin net P-type layer similar to 160 could also be formed by designing one or more N-type implants 140 to leave the desired doping and thickness of net P from partially compensated P-body 40.

A third embodiment of the present teachings is depicted in FIG. 16. This embodiment can include a DMOS transistor device having a trench gate and a recessed contact to the P-body 40 and the source 50, and a counterdoped Schottky or low-injection P-body diode. A P-type tuning implant can be employed to counterdope and form lower doped N-type regions 160 to adjust a barrier height and charge between P-body regions 40 which are laterally located on either side of the trench. The dose of the tuning implant in this embodiment which forms region 160 can be selected so that the implanted region 160 maintains a net N-type conductivity, unlike the FIG. 15 embodiment in which region 150 has a net P-type conductivity. In this embodiment, the metal formed during subsequent processing (similar to metal 100, 102 of FIG. 10) provides a Schottky contact to the N-type region 160. The FIG. 16 structure can be formed using processing techniques similar to those previously described.

FIG. 17 is a technology computer aided design (TCAD) simulation depicting three embodiments 180, 190, and 200 of the present teachings in which a lower extent of the P-body region 40 is below the Schottky. As with previous embodiments, the Schottky is formed at the interface between the metal within the trench and the silicon which forms the bottom of the trench. In embodiment 180, the Schottky is provided at 186 and a P-body junction is provided at the interface of P-type region 182 and N-type region 184. In embodiment 190, the Schottky is provided at 196 and a P-body junction is provided at the interface of P-type region 192 and N-type region 194. In embodiment 200, the Schottky is provided at 206 and the P-body junction is provided at the interface of P-type region 202 and N-type region 204. These simulations were performed on a device similar to that of FIG. 14, with different etch depths through the P-body contacts and into the substrate. In structure 180, the lower extent of the P-body 182 is just below the Schottky 186. In structure 190, the lower extent of the P-body 192 is further below the Schottky 196 than in structure 180. In structure 200, the P-body 202 is significantly below the Schottky 206.

The extent to which the bottom of the P-body is below the Schottky can be controlled by the depth of the etch which forms the trench into which the metal is deposited (which controls the thickness “T” as referenced relative to FIG. 8), as well as the doping of the substrate at the bottom of the trench. Both the depth which adjusts “T” and the doping (using, for example, tuning implants as described) can be controlled to result in a device having the desired electrical characteristics.

FIG. 18 is a graph depicting reverse current and voltage characteristics of three devices, with each device including a Schottky contact and a P-body. These devices can have a low leakage which can result from a lower extent of the P-body being below a level of the Schottky contact. The data set of line 212 corresponds to structure 180 of FIG. 18 where “T” is 0.01 μm, and the data set of line 214 corresponds to structure 190 of FIG. 18 where “T” is 0.06 μm. An N-compensation implant results in an N-compensation region which converts the P-body region in the substrate directly below the Schottky contact opening to have a net N-type conductivity with an approximate dose of about 1E13 atoms/cm².

Data set 216 depicts a device in which the P-body is located below the Schottky through the use of a shallow etch which increases “T” to a very large number. An N-compensation region is formed, but in this case a much higher charge is needed to overcome the doping of the P-body implant. The resulting region has an N-type charge that is much higher than 1E13 atoms/cm², and results in a device having a very high leakage. A tuning implant using a P-type dopant, for example in accordance with FIG. 15, can reduce the leakage for this embodiment.

FIG. 19 is a graph depicting forward current and voltage characteristics of a Schottky in accordance with the three structures of FIG. 18. The depth of the opening to adjust “T” and the doping levels can be adjusted for each specific device such that the forward current and voltage (“IV”) characteristics can be enhanced for improved device performance. It can be seen that the improvement in reverse IV characteristics of the FIG. 18 devices avoids the significant degradation in forward IV characteristics found with conventional methods and structures.

Thus a device formed according to the present teachings can include one or more of various characteristics. For example, a Schottky contact can be located in every MOSFET, but the Schottky does not increase the size of the device as the Schottky does not require any additional active area. Additionally, a single P-body region can be provided between transistor gate locations. Further, the Schottky contact is shallower than the P-body region. Additionally, deep P-regions on each side of the Schottky contact which has a lower extent which is below a level of the Schottky between the Schottky contact edges and the transistor gate trench, can form a shield which reduces leakage. In one embodiment, the dose and energy of compensation implant is chosen to ensure that a net doping (i.e. charge) of the substrate remaining between opposing P-body regions (i.e. P-body regions on either side of the trench) has a dose of between about 1E11 atoms/cm² and about 1E13 atoms/cm² for improved forward and leakage characteristics. One or more of these characteristics can be accomplished using only one additional mask, and without the need for special or additional Schottky metal.

Various embodiments prevents the need for a “split P-body,” resulting in a decreased distance between transistor gates than if a split P-body was formed. The Schottky is shielded (guarded) by deeper P-type regions on each side, which can be achieved using the described compensation implant. A charge between opposing P-body regions can be have an implant dose of within about 1E11 atoms/cm² and about 1E13 atoms/cm², which can result from a tuning implant to improve the charge.

As discussed above, the exemplary methods and structures are used to form an NMOS device, and various structures are referred to as a “P-body,” a “P-body contact,” an “N-compensation region,” a “P-body junction,” etc. Broadly, these structures are referred to as a “body,” a “body contact,” a “compensation region,” and a “body junction” respectively for methods used to form either PMOS devices or NMOS devices.

Various semiconductor devices may be attached along with other semiconductor devices such as a microprocessor to a printed circuit board, for example to a computer motherboard or as a part of a memory module used in a personal computer, a minicomputer, a mainframe, or another electronic system. In a particular embodiment, depicted in the block diagram of FIG. 20, the guarded Schottky 220 can be formed in a voltage regulator device 222, and provided for use within an electrical system 224. A device may be used in other electronic devices, for example devices including a microprocessor, related to telecommunications, the automobile industry, semiconductor test and manufacturing equipment, consumer electronics, or virtually any piece of consumer or industrial electronic equipment.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

While the disclosure has been illustrated with respect to one or more implementations, alterations and/or modifications can be made to the illustrated examples without departing from the spirit and scope of the appended claims. In addition, while a particular feature of the present teachings may have been disclosed with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the present teachings will be apparent to those skilled in the art from consideration of the specification and practice of the disclosure. It is intended that the specification and examples be considered as exemplary only, with a true scope and spirit of the present teachings being indicated by the following claims.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

1. A method for forming a semiconductor device, comprising:
etching a semiconductor substrate to form a trench therein, the trench comprising a first sidewall, a second sidewall, and a bottom;
implanting a dopant having a first type conductivity into the semiconductor substrate at the bottom of the trench and into the first sidewall and the second sidewall of the trench to form a body contact region;
etching through a thickness of the body contact region at the bottom of the trench to remove a portion of the implanted body contact region such that a first portion and a second portion of the implanted body contact region remain in the first and second sidewalls respectively, wherein the first portion and the second portion of the implanted body contact region are disposed between a Schottky diode region and a transistor gate location; and
implanting the semiconductor substrate at the bottom of the trench with a dopant having a second type conductivity opposite to the first type conductivity.

2. The method of claim 1, further comprising:
adjusting a barrier height of the Schottky diode by implanting a dopant having the first type conductivity into the semiconductor substrate at the bottom of the trench.

3. The method of claim 2 wherein, after forming the body contact region and adjusting a barrier height of the Schottky diode, a net conductivity of the semiconductor substrate at the bottom of the trench is the first type conductivity.

4. The method of claim 2 wherein, after forming the body contact region and adjusting a barrier height of the Schottky diode, a net conductivity of the semiconductor substrate at the bottom of the trench is the second type conductivity.

5. The method of claim 1, further comprising:
forming at least one conductor within the trench,
wherein the etching through the thickness of the body contact region, the implanting of the dopant having the first type conductivity into the substrate at the bottom of the trench, and the formation of the at least one conductor within the trench results in the formation of the Schottky diode at a location above a body junction.

6. The method of claim 5, wherein the semiconductor substrate is doped to a net first conductivity type and the method further comprises:
during the implanting of the dopant having the second type conductivity into the substrate at the bottom of the trench, doping the bottom of the trench with a dopant having a second conductivity type opposite of the first conductivity type to a concentration sufficient to change a net dopant concentration from the first conductivity type to the second conductivity type.

7. The method of claim 6, further comprising:
implanting the substrate at the bottom of the trench with a dopant having the first conductivity type to a concentration which is sufficient to change a net doping concentration of the substrate at the bottom of the trench from the second conductivity type to the first conductivity type.

8. The method of claim 6, further comprising:
implanting the substrate at the bottom of the trench with a dopant having the first conductivity type to a concentration which is insufficient to change a net doping concentration of the substrate at the bottom of the trench from the second conductivity type to the first conductivity type.

9. A semiconductor device, comprising:
a semiconductor substrate;
a plurality of transistors formed within the semiconductor substrate, wherein each transistor comprises:
a trench having a first sidewall, a second sidewall, and a bottom;
a body comprising a first body contact region and a second body contact region which abut the first sidewall and the second sidewall respectively;
a Schottky diode at an interface of the bottom of the trench and a conductor within the trench,
wherein a lower extent of the body is below the Schottky diode formed at the interface between the bottom of the trench and the conductor within the trench.

10. The semiconductor device of claim 9, wherein at least a portion of the body is shallower than the trench bottom.

11. The semiconductor device of claim 9, wherein the body extends between about 0.01 μm and about 0.4 μm below the Schottky diode.

12. A semiconductor device, comprising:
a semiconductor substrate having a trench therein, the trench comprising a first sidewall, a second sidewall, and a bottom;
a body comprising a body contact region which abuts the first sidewall and the second sidewall, the body contact region comprising a first concentration of a dopant having a first conductivity type;
at least one conductive layer which fills the trench;
a compensation region within the substrate at the bottom of the trench, wherein the compensation region has a second concentration of the dopant having the first conductivity type and the second concentration is less than the first concentration; and
the compensation region within the substrate at the bottom of the trench further comprises a concentration of a dopant having a second conductivity type opposite of the first conductivity type.

13. The semiconductor device of claim 12, further comprising:
the compensation region within the substrate at the bottom of the trench has a net concentration of dopants having the first conductivity type.

14. The semiconductor device of claim 12, further comprising:
the compensation region within the substrate at the bottom of the trench has a net concentration of dopants having the second conductivity type.

15. An electronic system comprising a metal oxide semiconductor field effect transistor (MOSFET), wherein the MOSFET comprises:
a semiconductor substrate;
a plurality of transistors formed within the semiconductor substrate, wherein each transistor comprises:
a trench having a first sidewall, a second sidewall, and a bottom;
a body comprising a first body contact region and a second body contact region which abut the first sidewall and the second sidewall respectively;
a Schottky diode at an interface of the bottom of the trench and a conductor within the trench,
wherein a lower extent of the body is below the Schottky diode formed at the interface between the bottom of the trench and the conductor within the trench.

16. The electronic system of claim 15, wherein at least a portion of the body of the MOSFET is shallower than the trench bottom.

17. The electronic system of claim 15, further comprising:
a voltage regulator; and
the voltage regulator includes the MOSFET.
